(19) United States
(12) Patent Application Publication
(10) Pub. No.: US 2024/0425694 A1
(43) Pub. Date: Dec. 26, 2024

(54) RESIN COMPOSITION FOR FORMING PHASE-SEPARATED STRUCTURE, AND METHOD FOR PRODUCING STRUCTURE BODY INCLUDING PHASE-SEPARATED STRUCTURE

(71) Applicant: TOKYO OHKA KOGYO CO., LTD., Kawasaki-shi (JP)

(72) Inventors: Ken Miyagi, Kawasaki-shi (JP); Takahiro Dazai, Kawasaki-shi (JP); Junichi Tsuchiya, Kawasaki-shi (JP)

(21) Appl. No.: 18/692,782

(22) PCT Filed: Sep. 20, 2022
(86) PCT No.: PCT/JP2022/034898

§ 371 Date: Mar. 15, 2024

(30) Foreign Application Priority Data
Sep. 22, 2021 (JP) 2021-154455
Mar. 14, 2022 (JP) 2022-039583

(51) Int. Cl. C08L 53/00

(52) U.S. Cl. CPC C08L 53/00; C08L 2205/025; C08L 2205/035

(57) ABSTRACT

A resin composition for forming a phase-separated structure, the resin composition containing a first block copolymer having a first a block and a first b block, a second block copolymer having a second a block and a second b block, a homopolymer A compatible with the first a block and the second a block, and a homopolymer B compatible with the first b block and the second b block, in which a constitutional unit constituting the first a block and a constitutional unit constituting the second a block are the same, a constitutional unit constituting the first b block and a constitutional unit constituting the second b block are the same, and a number-average molecular weight of the second block copolymer is larger than a number-average molecular weight of the first block copolymer.

### TECHNICAL FIELD

The present invention relates to a resin composition for forming a phase-separated structure and a method for producing a structure body including a phase-separated structure.

Priority is claimed on Japanese Patent Application No. 2021-154455, filed on Sep. 22, 2021, and Japanese Patent Application No. 2022-039583, filed on Mar. 14, 2022, the contents of which are incorporated herein by reference.

### BACKGROUND ART

In recent years, along with further miniaturization of large-scale integrated circuits (LSI), a technology for processing finer structure bodies has been demanded.

In response to such a demand, there has been developed a technology for forming a finer pattern by utilizing a phase-separated structure formed by self-organization of a block copolymer in which blocks incompatible to each other are bonded together (for example, see Patent Document 1).

The block copolymer is separated (phase-separated) in micro regions due to repulsion between blocks incompatible with each other, and subjected to a heat treatment or the like to form a structure body having a regular periodic structure. As the periodic structure, specifically, a cylinder (columnar phase), a lamella (plate phase), a sphere (spherical phase), and the like are exemplary examples.

In order to utilize the phase-separated structure of the block copolymer, it is considered essential to form self-organized nanostructures, which are formed by micro-phase separation, only in a specific region and arrange the nanostructures in a desired direction. In order to realize the position control and orientation control of these nanostructures, processes such as graphoepitaxy for controlling the phase separation pattern by a guide pattern, and chemical epitaxy for controlling the phase separation pattern by the difference in the chemical state of the substrate, have been proposed (for example, see Non-Patent Document 1).

As a resin composition containing such a block copolymer, for example, Patent Document 2 discloses a resin composition for forming a phase-separated structure, which contains a resin component including three components of a block copolymer, a first homopolymer compatible with a first block in the block copolymer, and a second homopolymer compatible with a second block in the block copolymer, in which a compositional ratio of the first homopolymer and the second homopolymer in the resin component is substantially the same as a compositional ratio of the first block and the second block in the block copolymer.

### CITATION LIST

### Patent Documents

### [Patent Document 1]

Japanese Unexamined Patent Application, First Publication No. 2008-36491

### [Patent Document 2]

Japanese Unexamined Patent Application, First Publication No. 2016-065215

### Non-Patent Literature

### [Non-Patent Document 1]

Proceedings of SPI, Vol. 7637, No. 76370G-1 (2010).

### SUMMARY OF INVENTION

### Technical Problem

As the miniaturization of the structure body including a phase-separated structure progresses, for example, in a case where the phase separation pattern is controlled by the guide pattern, it is possible to control the position and orientation of the phase separation pattern even in a case where the guide pattern dimensions vary by approximately several nm.

Therefore, it is necessary to improve the process margin in the production of the structure body including a phase-separated structure.

Since the resin composition for forming a phase-separated structure, disclosed in Patent Document 2, contains a plurality of specific homopolymers in addition to the block copolymer, the process margin is relatively large.

However, in the resin composition for forming a phase-separated structure, disclosed in Patent Document 2, although the process margin is improved, there is a problem in that defects (surface defects) are likely to occur. In this way, the improvement of the process margin and the suppression of the occurrence of defects have a trade-off relationship, and it is difficult to achieve both.

The present invention has been made in view of the above circumstances, and an object of the present invention is to provide a resin composition for forming a phase-separated structure, in which occurrence of defects can be suppressed while improving process margin, and a method for producing a structure body including a phase-separated structure, using the resin composition for forming a phase-separated structure.

### Solution to Problem

A first aspect of the present invention is a resin composition for forming a phase-separated structure, containing a first block copolymer having a first a block and a first b block, a second block copolymer having a second a block and a second b block, a homopolymer A compatible with the first a block and the second a block, and a homopolymer B compatible with the first b block and the second b block, in which a constitutional unit constituting the first a block and a constitutional unit constituting the second a block are the same, a constitutional unit constituting the first b block and a constitutional unit constituting the second b block are the same, and a number-average molecular weight of the second block copolymer is larger than a number-average molecular weight of the first block copolymer.

A second aspect of the present invention is a method for producing a structure body including a phase-separated structure, the method including a step of applying the resin composition for forming a phase-separated structure according to the first aspect onto a support to form a layer containing the resin composition for forming a phase-separated structure, and a step of phase-separating the layer containing the resin composition for forming a phase-separated structure.

### Advantageous Effects of Invention

According to the present invention, it is possible to provide a resin composition for forming a phase-separated structure, in which occurrence of defects can be suppressed while improving process margin, and a method for producing a structure body including a phase-separated structure, using the resin composition for forming a phase-separated structure.

### BRIEF DESCRIPTION OF DRAWINGS

FIG. 1 is a schematic process diagram showing an exemplary embodiment of a method for producing a structure body including a phase-separated structure.

FIG. 2 is a diagram showing an exemplary embodiment of an optional step.

### DESCRIPTION OF EMBODIMENTS

In the present specification and the scope of the present claims, the term “aliphatic” is a relative concept used with respect to “aromatic” and defines a group or compound that has no aromaticity.

A term “alkyl group” includes linear, branched, or cyclic monovalent saturated hydrocarbon groups unless otherwise specified. The same applies to an alkyl group in an alkoxy group.

A term “alkylene group” includes linear, branched, or cyclic divalent saturated hydrocarbon groups unless otherwise specified.

A “halogenated alkyl group” is a group in which a part of or all of hydrogen atoms in an alkyl group are substituted with halogen atoms. As the halogen atom, a fluorine atom, a chlorine atom, a bromine atom, and an iodine atom are exemplary examples.

The “fluorinated alkyl group” or a “fluorinated alkylene group” is a group obtained by substituting part or all of hydrogen atoms of an alkyl group or an alkylene group with a fluorine atom.

A term “constitutional unit” indicates a monomer unit constituting a polymer compound (a resin, a polymer, or a copolymer).

A phrase “constitutional unit derived from” means a constitutional unit that is formed by the cleavage of an ethylenic double bond.

An expression “may have a substituent” includes a case where a hydrogen atom (—H) is substituted with a monovalent group and a case where a methylene group (—CH₂—) is substituted with a divalent group.

A term “exposure” is used as a general concept for irradiation with radiation.

The term “α-position (carbon atom at α-position)” means a carbon atom to which a side chain of a block copolymer is bonded, unless otherwise specified. The “carbon atom at the α-position” of a methyl methacrylate unit means a carbon atom to which a carbonyl group of methacrylic acid is bonded. The “carbon atom at the α-position” of a styrene unit means a carbon atom to which a benzene ring is bonded.

The term “number-average molecular weight” (Mn) is the number-average molecular weight in terms of standard polystyrene measured by size-exclusion chromatography, unless otherwise specified.

A term “weight-average molecular weight” (Mw) is a weight-average molecular weight in terms of standard polystyrene measured by size-exclusion chromatography, unless otherwise specified. A value obtained by adding a unit (gmol-) to the value of Mn or Mw represents a molar mass.

In the detailed description and claims of the present invention, in the specification and claims of the present invention, some structures represented by a chemical formula have an asymmetric carbon, and there may be enantiomers and diastereomers. Those isomers are collectively represented by one formula. These isomers may be used alone or in the form of a mixture.

In the present specification, a phrase “period of a structure body” means the period of the phase structure observed when the structure body of a phase-separated structure is formed and refers to the sum of the lengths of the phases each of which is incompatible. In a case where the phase-separated structure forms a cylinder structure perpendicular to a surface of the substrate, the period (L0) of the structure body is the distance (pitch) between centers of two adjacent cylinder structures.

It is known that the period (L0) of the structure body is determined by inherent polymerization properties such as the degree of polymerization N and interaction parameter χ of Flory-Huggins. That is, as the product “χ×N” of χ and N is larger, the mutual repulsion between the different blocks in the block copolymer is greater. Therefore, in a case of the relation of χ×N>10.5 (hereinafter, referred to as “strong separation limit”), the repulsion between the different kinds of blocks in the block copolymer is large, and the tendency for phase separation to occur is strong. Accordingly, in the strong separation limit, the period of the structure body is approximately N^{2/3}×χ^{1/6} and satisfies the relationship of the following expression (cy). That is, the period of the structure body is proportional to the degree of polymerization N, which correlates with the molecular weight and the molecular weight ratio between the different blocks.

$$L 0 + ∝ a \times {N}^{2 / 3} \times {χ}^{1 / 6} \qquad ( cy )$$

[in the expression, L0 represents a period of the structure body, α is a parameter indicating the size of the monomer, N represents a degree of polymerization, and χ is an interaction parameter, in which the value thereof is higher, the phase separation performance is higher]

Accordingly, the period (L0) of the structure body can be controlled by adjusting the composition and the total molecular weight of the block copolymer.

### (Resin Composition for Forming Phase-Separated Structure)

The resin composition for forming a phase-separated structure according to the present embodiment is a resin composition for forming a phase-separated structure, containing a first block copolymer having a first a block and a first b block, a second block copolymer having a second a block and a second b block, a homopolymer A compatible with the first a block and the second a block, and a homopolymer B compatible with the first b block and the second b block, in which a constitutional unit constituting the first a block and a constitutional unit constituting the second a block are the same, a constitutional unit constituting the first b block and a constitutional unit constituting the second b block are the same, and a number-average molecular weight of the second block copolymer is larger than a number-average molecular weight of the first block copolymer.

### <First Block Copolymer>

The first block copolymer is a polymer compound in which a plurality of types of blocks (partial structural components in which constitutional units of the same type are repeatedly bonded) are bonded.

The first block copolymer has at least the first a block and the first b block, and may have a block other than the first a block and the first b block.

The first a block and the first b block are not particularly limited as long as they form a combination which undergoes phase separation, but a combination of blocks which are incompatible with each other is preferable.

In addition, in a case where a layer containing the first block copolymer is formed, a combination in which a layer formed of the first a block or the first b block can be selectively removed more easily than a layer formed of other blocks is preferable.

As the first block copolymer, for example, a block copolymer in which a block of a constitutional unit having an aromatic hydrocarbon group and a block of a constitutional unit derived from an (α-substituted)acrylic acid ester are bonded with each other; a block copolymer in which a block of a constitutional unit having an aromatic hydrocarbon group and a block of a constitutional unit derived from an (α-substituted) acrylic acid are bonded with each other; a block copolymer in which block of a constitutional unit having an aromatic hydrocarbon group and a block of a constitutional unit derived from siloxane or a derivative thereof are bonded with each other; a block copolymer in which a block of a constitutional unit derived from alkylene oxide and a block of a constitutional unit derived from an (α-substituted)acrylic acid ester are bonded with each other; a block copolymer in which a block of a constitutional unit derived from alkylene oxide and a block of a constitutional unit derived from an (α-substituted) acrylic acid are bonded with each other; a block copolymer in which a block of a constitutional unit containing a cage silsesquioxane structure and a block of a constitutional unit derived from an (α-substituted) acrylic acid ester are bonded with each other; a block copolymer in which a block of a constitutional unit containing a cage silsesquioxane structure and a block of a constitutional unit derived from an (α-substituted) acrylic acid are bonded with each other; a block copolymer in which a constitutional unit containing a cage silsesquioxane structure and a block of a constitutional unit derived from siloxane or a derivative thereof are bonded with each other; and the like are exemplary examples.

### <<Constitutional Unit Having Aromatic Hydrocarbon Group>>

The aromatic hydrocarbon group in the constitutional unit having an aromatic hydrocarbon group is a hydrocarbon group having at least one aromatic ring.

The aromatic ring is not particularly limited as long as the aromatic ring is a cyclic conjugated system having 4n+2π electrons, and may be an aromatic heterocyclic ring in which a part of carbon atoms constituting the aromatic hydrocarbon ring is substituted with heteroatoms.

As the aromatic hydrocarbon group in the constitutional unit having an aromatic hydrocarbon group, specifically, a phenyl group, a naphthyl group, and the like are exemplary examples.

Among the above, as the constitutional unit having an aromatic hydrocarbon group, a constitutional unit derived from styrene, a styrene derivative, 1-vinylnaphthalene, 4-vinylbiphenyl, 1-vinyl-2-pyrrolidone, 9-vinylanthracene, or vinylpyridine is preferable, and a constitutional unit derived from styrene or a styrene derivative is more preferable.

As the styrene or the styrene derivative, specifically, α-methylstyrene, 2-methylstyrene, 3-methylstyrene, 4-methylstyrene, 4-t-butylstyrene, 4-n-octylstyrene, and 2,4,6-trimethylstyrene, 4-methoxystyrene, 4-t-butoxystyrene, 4-hydroxystyrene, 4-nitrostyrene, 3-nitrostyrene, 4-chlorostyrene, 4-fluorostyrene, 4-acetoxyvinylstyrene, 4-chloromethylstyrene, and the like are exemplary examples.

<<Constitutional Unit Derived from (α-Substituted) Acrylic Acid Ester>>

In the present specification, the “(α-substituted) acrylic acid ester” includes an acrylic acid ester and a derivative in which a hydrogen atom bonded to a carbon atom at an α-position of the acrylic acid ester is substituted with a substituent.

As the (α-substituted)acrylic acid ester, specifically, acrylic acid esters such as methyl acrylate, ethyl acrylate, propyl acrylate, n-butyl acrylate, t-butyl acrylate, cyclohexyl acrylate, octyl acrylate, nonyl acrylate, hydroxyethyl acrylate, hydroxypropyl acrylate, benzyl acrylate, anthracene acrylate, glycidyl acrylate, 3,4-epoxycyclohexylmethane acrylate, and propyltrimethoxysilane acrylate; methacrylic acid esters such as methyl methacrylate, ethyl methacrylate, propyl methacrylate, n-butyl methacrylate, t-butyl methacrylate, cyclohexyl methacrylate, octyl methacrylate, nonyl methacrylate, hydroxyethyl methacrylate, hydroxypropyl methacrylate, benzyl methacrylate, anthracene methacrylate, glycidyl methacrylate, 3,4-epoxycyclohexylmethane methacrylate, and propyltrimethoxysilane methacrylate; and the like are exemplary examples.

Among the above, as the (α-substituted) acrylic acid ester, methyl acrylate, ethyl acrylate, t-butyl acrylate, methyl methacrylate, ethyl methacrylate, or t-butyl methacrylate is preferable, and methyl methacrylate is more preferable.

<<Constitutional Unit Derived from (α-Substituted) Acrylic Acid>>

In the present specification, the “(α-substituted) acrylic acid” includes an acrylic acid and a derivative in which a hydrogen atom bonded to a carbon atom at an α-position of the acrylic acid is substituted with a substituent.

As the (α-substituted) acrylic acid, specifically, acrylic acid, methacrylic acid, and the like are exemplary examples.

<<Constitutional Unit Derived from Siloxane or Derivative Thereof>>

As the siloxane or a derivative thereof, specifically, dimethylsiloxane, diethylsiloxane, diphenylsiloxane, methylphenylsiloxane, and the like are exemplary examples.

<<Constitutional Unit Derived from Alkylene Oxide>>

As the alkylene oxide, specifically, ethylene oxide, propylene oxide, isopropylene oxide, butylene oxide, and the like are exemplary examples.

<<Constitutional Unit Derived from Constitutional Unit Containing Cage Silsesquioxane Structure>>

As the constitutional unit containing a cage silsesquioxane (POSS) structure, a constitutional unit represented by General Formula (a0-1) is an exemplary example.

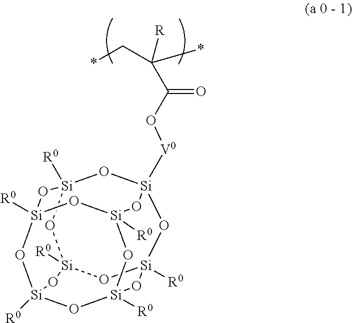

[in the formula, R represents a hydrogen atom, an alkyl group having 1 to 5 carbon atoms, or a halogenated alkyl group having 1 to 5 carbon atoms, V⁰ represents a divalent hydrocarbon group which may have a substituent, R⁰ represents a monovalent hydrocarbon group which may have a substituent, and a plurality of R⁰'s may be the same or different from each other, and * represents a bonding site]

In Formula (a0-1), as the alkyl group having 1 to 5 carbon atoms as R, a linear or branched alkyl group having 1 to 5 carbon atoms is preferable, and specifically, a methyl group, an ethyl group, a propyl group, an isopropyl group, an n-butyl group, an isobutyl group, a tert-butyl group, a pentyl group, an isopentyl group, a neopentyl group, and the like are exemplary examples. The halogenated alkyl group having 1 to 5 carbon atoms is a group in which a part of or all hydrogen atoms in the alkyl group having 1 to 5 carbon atoms are substituted with halogen atoms. As the halogen atom, a fluorine atom, a chlorine atom, a bromine atom, and an iodine atom are exemplary examples. Among these, a fluorine atom is particularly preferable.

As R, a hydrogen atom, an alkyl group having 1 to 5 carbon atoms, or a fluorinated alkyl group having 1 to 5 carbon atoms is preferable, and a hydrogen atom or a methyl group is most preferable from the viewpoint of industrial availability.

In Formula (a0-1), the number of carbon atoms in the monovalent hydrocarbon group as R⁰ is preferably 1 to 20, more preferably 1 to 10, and still more preferably 1 to 8. Here, the number of carbon atoms does not include the number of carbon atoms in a substituent described later.

The monovalent hydrocarbon group as R⁰ may be an aliphatic hydrocarbon group or an aromatic hydrocarbon group, and an aliphatic hydrocarbon group is preferable and a monovalent aliphatic saturated hydrocarbon group (alkyl group) is more preferable.

As the above-described alkyl group, more specifically, a chain-like aliphatic hydrocarbon group (linear or branched alkyl group), an aliphatic hydrocarbon group including a ring in the structure, and the like are exemplary examples.

The number of carbon atoms in the linear alkyl group is preferably 1 to 8, more preferably 1 to 5, and still more preferably 1 to 3. Specifically, a methyl group, an ethyl group, an n-propyl group, an isopropyl group, an n-butyl group, an isobutyl group, an n-pentyl group, and the like are exemplary examples. Among these, a methyl group, an ethyl group, or an n-propyl group is preferable, a methyl group, an ethyl group, or an isobutyl group is more preferable, an ethyl group or an isobutyl group is still more preferable, and an ethyl group is particularly preferable.

The number of carbon atoms in the branched alkyl group is preferably 3 to 5. Specifically, an isopropyl group, an isobutyl group, a tert-butyl group, an isopentyl group, a neopentyl group, and the like are exemplary examples, and an isopropyl group or a tert-butyl group is most preferable.

As the aliphatic hydrocarbon group including a ring in the structure, a cyclic aliphatic hydrocarbon group (a group formed by removing one hydrogen atom from an aliphatic hydrocarbon ring), a group in which the cyclic aliphatic hydrocarbon group is bonded to a terminal of the above-described chain-like aliphatic hydrocarbon group, and a group in which the cyclic aliphatic hydrocarbon group is interposed in the above-described chain-like aliphatic hydrocarbon group, and the like are exemplary examples.

The number of carbon atoms in the cyclic aliphatic hydrocarbon group is preferably 3 to 8 and more preferably 4 to 6, and the cyclic aliphatic hydrocarbon group may be a polycyclic group or a monocyclic group. The monocyclic group is preferably a group formed by removing one or more hydrogen atoms from a monocycloalkane having 3 to 6 carbon atoms, and as the monocycloalkane, cyclopentane, cyclohexane, and the like are exemplary examples. As the polycyclic group, a group formed by removing one or more hydrogen atoms from a polycycloalkane having 7 to 12 carbon atoms is preferable, and as the polycycloalkane, specifically, adamantane, norbornane, isobornane, tricyclodecane, tetracyclododecane, and the like are exemplary examples.

The chain-like aliphatic hydrocarbon group may have a substituent. As the substituent, a fluorine atom, a fluorinated alkyl group having 1 to 5 carbon atoms, which is substituted with a fluorine atom, an oxygen atom (═O), and the like are exemplary examples.

The cyclic aliphatic hydrocarbon group may have a substituent. As the substituent, an alkyl group having 1 to 5 carbon atoms, a fluorine atom, a fluorinated alkyl group having 1 to 5 carbon atoms, an oxygen atom (═O), and the like are exemplary examples.

In a case where the monovalent hydrocarbon group as R⁰ is an aromatic hydrocarbon group, the aromatic hydrocarbon group is a monovalent hydrocarbon group having at least one aromatic ring.

The aromatic ring is not particularly limited as long as the aromatic ring has a cyclic conjugated system having (4n+2) pieces of π electrons, and may be monocyclic or polycyclic. The number of carbon atoms in the aromatic ring is preferably 5 to 30, more preferably 5 to 20, still more preferably 6 to 15, and particularly preferably 6 to 12. Here, the number of carbon atoms does not include the number of carbon atoms in a substituent described later.

As specific examples of the aromatic ring, aromatic hydrocarbon rings such as benzene, naphthalene, anthracene, and phenanthrene; an aromatic heterocyclic ring obtained by substituting a part of carbon atoms constituting the above-described aromatic hydrocarbon ring with a heteroatom; and the like are exemplary examples. As the heteroatom in the aromatic heterocyclic ring, an oxygen atom, a sulfur atom, and a nitrogen atom are exemplary examples. Specifically, as the aromatic heterocyclic ring, a pyridine ring and a thiophene ring are exemplary examples.

As the aromatic hydrocarbon group, specifically, a group (an aryl group or a heteroaryl group) formed by removing one hydrogen atom from the aromatic hydrocarbon ring or aromatic heterocyclic ring; a group formed by removing one hydrogen atom from an aromatic compound (for example, biphenyl, fluorene, or the like) having two or more aromatic rings; a group (for example, an arylalkyl group such as a benzyl group, a phenethyl group, a 1-naphthylmethyl group, a 2-naphthylmethyl group, a 1-naphthylethyl group, and a 2-naphthylethyl group) in which one hydrogen atom in an aromatic hydrocarbon ring or aromatic heterocyclic ring is substituted with an alkylene group; and the like are exemplary examples.

The number of carbon atoms in the alkylene group which is bonded to the above-described aryl group or heteroaryl group is preferably 1 to 4, more preferably 1 or 2, and particularly preferably 1.

The aromatic hydrocarbon group may or may not have a substituent. As the substituent, an alkyl group having 1 to 5 carbon atoms, a fluorine atom, a fluorinated alkyl group having 1 to 5 carbon atoms, which is substituted with a fluorine atom, an oxygen atom (═O), and the like are exemplary examples.

In Formula (a0-1), the divalent hydrocarbon group as V⁰ may be an aliphatic hydrocarbon group or an aromatic hydrocarbon group. The aliphatic hydrocarbon group indicates a hydrocarbon group with no aromaticity.

The aliphatic hydrocarbon group as the divalent hydrocarbon group represented by V⁰ may be saturated or unsaturated, and in general, it is preferable that the aliphatic hydrocarbon group is saturated.

More specifically, as the aliphatic hydrocarbon group, a linear or branched aliphatic hydrocarbon group and an aliphatic hydrocarbon group including a ring in the structure thereof are exemplary examples.

The number of carbon atoms in the above-described linear or branched aliphatic hydrocarbon group is preferably 1 to 10, more preferably 1 to 6, still more preferably 1 to 4, and most preferably 1 to 3.

As the linear aliphatic hydrocarbon group, a linear alkylene group is preferable, and specifically, a methylene group [—CH₂—], an ethylene group [—(CH₂)₂—], a trimethylene group [—(CH₂)₃—], a tetramethylene group [—(CH₂)₄—], a pentamethylene group [—(CH₂)₅—], and the like are exemplary examples.

As the branched aliphatic hydrocarbon group, a branched alkylene group is preferable, and specifically, alkylalkylene groups, for example, alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)—, and —C(CH₂CH₃)₂—; alkylethylene groups such as —CH(CH₃)CH₂—, —CH(CH₃)CH(CH₃)—, —C(CH₃)₂CH₂—, —CH(CH₂CH₃)CH₂—, and —C(CH₂CH₃)₂—CH₂—; alkyltrimethylene groups such as —CH(CH₃)CH₂CH₂— and —CH₂CH(CH₃)CH₂—; and alkyltetramethylene groups such as —CH(CH₃)CH₂CH₂CH₂— and —CH₂CH(CH₃)CH₂CH₂— are exemplary examples. As an alkyl group in the alkylalkylene group, a linear alkyl group having 1 to 5 carbon atoms is preferable.

As the aliphatic hydrocarbon group including a ring in the structure thereof, an alicyclic hydrocarbon group (a group formed by removing two hydrogen atoms from an aliphatic hydrocarbon ring), a group in which an alicyclic hydrocarbon group is bonded to the terminal of a linear or branched aliphatic hydrocarbon group, and a group in which an alicyclic hydrocarbon group is interposed in a linear or branched aliphatic hydrocarbon group are exemplary examples. As the linear or branched aliphatic hydrocarbon group, the same as those described above is an exemplary example.

The number of carbon atoms in the alicyclic hydrocarbon group is preferably 3 to 20 and more preferably 3 to 12.

The alicyclic hydrocarbon group may be a polycyclic group or a monocyclic group. As the monocyclic alicyclic hydrocarbon group, a group formed by removing two hydrogen atoms from a monocycloalkane is preferable. The number of carbon atoms in the monocycloalkane is preferably 3 to 6, and specifically, cyclopentane and cyclohexane are exemplary examples.

As the polycyclic alicyclic hydrocarbon group, a group formed by removing two hydrogen atoms from a polycycloalkane is preferable. The number of carbon atoms in the polycycloalkane is preferably 7 to 12, and specifically, adamantane, norbornane, isobornane, tricyclodecane, and tetracyclododecane are exemplary examples.

The aromatic hydrocarbon group is a hydrocarbon group having an aromatic ring.

The aromatic ring is not particularly limited as long as the aromatic ring has a cyclic conjugated system having (4n+2) pieces of π electrons, and may be monocyclic or polycyclic. The number of carbon atoms in the aromatic ring is preferably 5 to 30, more preferably 5 to 20, still more preferably 6 to 15, and particularly preferably 6 to 12. Here, the number of carbon atoms does not include the number of carbon atoms in a substituent described later.

As specific examples of the aromatic ring, aromatic hydrocarbon rings such as benzene, naphthalene, anthracene, and phenanthrene; an aromatic heterocyclic ring obtained by substituting a part of carbon atoms constituting the above-described aromatic hydrocarbon ring with a heteroatom; and the like are exemplary examples. As the heteroatom in the aromatic heterocyclic ring, an oxygen atom, a sulfur atom, and a nitrogen atom are exemplary examples. Specifically, as the aromatic heterocyclic ring, a pyridine ring and a thiophene ring are exemplary examples.

Specifically, as the aromatic hydrocarbon group, a group (an arylene group or a heteroarylene group) formed by removing two hydrogen atoms from the aromatic hydrocarbon ring or the aromatic heterocyclic ring; a group formed by removing two hydrogen atoms from an aromatic compound (for example, biphenyl, fluorene, or the like) having two or more aromatic rings; and a group (for example, a group in which one hydrogen atom is further removed from an aryl group in an arylalkyl group such as a benzyl group, a phenethyl group, a 1-naphthylmethyl group, a 2-naphthylmethyl group, a 1-naphthylethyl group, and a 2-naphthylethyl group) in which one hydrogen atom of a group (an aryl group or a heteroaryl group) formed by removing one hydrogen atom from the aromatic hydrocarbon ring or the aromatic heterocyclic ring is substituted with an alkylene group are exemplary examples.

The number of carbon atoms in the alkylene group which is bonded to the above-described aryl group or heteroaryl group is preferably 1 to 4, more preferably 1 or 2, and particularly preferably 1.

Specific examples of the constitutional unit represented by General Formula (a0-1) are shown below. In the formula shown below, R⁰ represents a hydrogen atom, a methyl group, or a trifluoromethyl group.

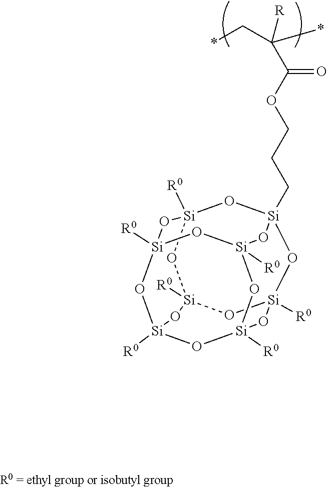

As the first block copolymer, more specifically, a block copolymer having a block of a constitutional unit derived from styrene and a block of a constitutional unit derived from acrylic acid; a block copolymer having a block of a constitutional unit derived from styrene and a block of a constitutional unit derived from methyl acrylate; a block copolymer having a block of a constitutional unit derived from styrene and a block of a constitutional unit derived from ethyl acrylate; a block copolymer having a block of a constitutional unit derived from styrene and a block of a constitutional unit derived from t-butyl acrylate; a block copolymer having a block of a constitutional unit derived from styrene and a block of a constitutional unit derived from methacrylic acid; a block copolymer having a block of a constitutional unit derived from styrene and a block of a constitutional unit derived from methyl methacrylate; a block copolymer having a block of a constitutional unit derived from styrene and a block of a constitutional unit derived from ethyl methacrylate; a block copolymer having a block of a constitutional unit derived from styrene and a block of a constitutional unit derived from t-butyl methacrylate; a block copolymer having a block of a constitutional unit containing a cage silsesquioxane (POSS) structure and a block of a constitutional unit derived from acrylic acid; a block copolymer having a block of a constitutional unit containing a cage silsesquioxane (POSS) structure and a block of a constitutional unit derived from methyl acrylate; and the like are exemplary examples.

Among the above, as the first block copolymer, it is preferable to include a block of a constitutional unit having an aromatic hydrocarbon group and a block of a constitutional unit derived from an (α-substituted)acrylic acid or (α-substituted)acrylic acid ester, it is more preferable to include a block of a constitutional unit having an aromatic hydrocarbon group and a block of a constitutional unit derived from an (α-substituted)acrylic acid ester, and it is still more preferable to include a block of a constitutional unit derived from styrene and a block of a constitutional unit derived from methyl methacrylate.

That is, in the first block copolymer, it is preferable that the first a block is the block of a constitutional unit having an aromatic hydrocarbon group, and the first b block is a block of a constitutional unit derived from an (α-substituted)acrylic acid or (α-substituted)acrylic acid ester; it is more preferable that the first a block is the block of a constitutional unit having an aromatic hydrocarbon group, and the first b block is the block of a constitutional unit derived from an (α-substituted)acrylic acid ester; and it is still more preferable that the first a block is the block of a constitutional unit derived from styrene and, the first b block is the block of a constitutional unit derived from methyl methacrylate.

More specifically, the first block copolymer is preferably a polystyrene-poly(methyl methacrylate) block copolymer.

In a case where the first block copolymer includes a constitutional unit (u1) having an aromatic hydrocarbon group (hereinafter, also referred to as “constitutional unit (u1)”) and a constitutional unit (u2) derived from an (α-substituted)acrylic acid or (α-substituted)acrylic acid ester (hereinafter, also referred to as “constitutional unit (u2)”), a mass ratio of the constitutional unit (u1) and the constitutional unit (u2) (content of constitutional unit (u1):content of constitutional unit (u2)) is preferably 60:40 to 90:10 and more preferably 60:40 to 80:20.

In a case where the mass ratio of the constitutional unit (u1) and the constitutional unit (u2) in the first block copolymer is within the above-described preferred range, with the resin composition for forming a phase-separated structure according to the present embodiment, a phase-separated structure body having a cylinder shape, which is oriented in a vertical direction with respect to a surface of a support, is easily obtained. In addition, the process margin in a case of forming the structure body can be further improved and the occurrence of defects can be further suppressed.

A number-average molecular weight (Mn) of the first block copolymer is preferably 30,000 to 200,000, more preferably 40,000 to 180,000, and still more preferably 45,000 to 150,000.

In a case where the number-average molecular weight (Mn) of the first block copolymer is within the above-described preferred range, the process margin is more likely to be improved and the occurrence of defects is more easily suppressed.

A dispersity (Mw/Mn) of the first block copolymer is preferably 1.0 to 3.0, more preferably 1.0 to 1.5, and still more preferably 1.0 to 1.3. Mw is a weight-average molecular weight.

### <Second Block Copolymer>

The second block copolymer is a block copolymer having a second a block and a second b block. A constitutional unit constituting the second a block is the same as the constitutional unit constituting the first a block in the first block copolymer described above. A constitutional unit constituting the second b block is the same as the constitutional unit constituting the first b block in the first block copolymer described above.

That is, in the second block copolymer, it is preferable that the second a block is the block of a constitutional unit having an aromatic hydrocarbon group, and the second b block is a block of a constitutional unit derived from an (α-substituted)acrylic acid or (α-substituted)acrylic acid ester; it is more preferable that the second a block is the block of a constitutional unit having an aromatic hydrocarbon group, and the second b block is the block of a constitutional unit derived from an (α-substituted)acrylic acid ester; and it is still more preferable that the second a block is the block of a constitutional unit derived from styrene and, the second b block is the block of a constitutional unit derived from methyl methacrylate.

In a case where the second block copolymer includes the constitutional unit (u1) having an aromatic hydrocarbon group and the constitutional unit (u2) derived from an (α-substituted) acrylic acid or (α-substituted) acrylic acid ester, the mass ratio of the constitutional unit (u1) and the constitutional unit (u2) (amount of constitutional unit (u1):content of constitutional unit (u2)) is preferably 60:40 to 90:10 and more preferably 60:40 to 80:20.

In a case where the mass ratio of the constitutional unit (u1) and the constitutional unit (u2) in the second block copolymer is within the above-described preferred range, with the resin composition for forming a phase-separated structure according to the present embodiment, a phase-separated structure body having a cylinder shape, which is oriented in a vertical direction with respect to a surface of a support, is easily obtained. In addition, the process margin in a case of forming the structure body can be further improved and the occurrence of defects can be further suppressed.

The mass ratio of the constitutional unit constituting the first a block and the constitutional unit constituting the first b block in the first block copolymer may be the same as or different from the mass ratio of the constitutional unit constituting the second a block and the constitutional unit constituting the second b block in the second block copolymer, and it is preferable that the mass ratios thereof are substantially the same. In the present specification, the “substantially the same” means that, in a case where the mass ratio (1a:1b) of the constitutional unit constituting the first a block and the constitutional unit constituting the first b block in the first block copolymer is X1a:Y1b (X1a+Y1b=100), the mass ratio (2a:2b) of the constitutional unit constituting the second a block and the constitutional unit constituting the second b block in the second block copolymer is X1a±10:Y1b±10 (X1a+Y1b=100).

In a case where the mass ratio of the constitutional unit constituting the first a block and the constitutional unit constituting the first b block in the first block copolymer is 60:40, the mass ratio of the constitutional unit constituting the second a block and the constitutional unit constituting the second b block in the second block copolymer is preferably in a range of 50:50 to 70:30.

A mass ratio of the first block copolymer and the second block copolymer as content of first block copolymer:content of second block copolymer is preferably 99:1 to 1:99, more preferably 80:20 to 20:80, still more preferably 70:30 to 30:70, and particularly preferably 60:40 to 40:60.

In a case where the mass ratio of the first block copolymer and the second block copolymer is within the above-described preferred range, the occurrence of defects can be further suppressed.

The total content of the first block copolymer and the second block copolymer is preferably 40% by mass or more, more preferably 40% by mass or more and 99.5% by mass or less, still more preferably 45% by mass or more and 99% by mass or less, and particularly preferably 50% by mass or more and 90% by mass or less with respect to 100% by mass of the total solid content of the resin composition for forming a phase-separated structure according to the present embodiment.

A number-average molecular weight (Mn) of the second block copolymer is larger than the number-average molecular weight (Mn) of the first block copolymer described above, and it is preferably 30,000 to 200,000, more preferably 40,000 to 180,000, and still more preferably 45,000 to 150,000.

In a case where the number-average molecular weight (Mn) of the second block copolymer is within the above-described preferred range, the process margin is more likely to be improved and the occurrence of defects is more easily suppressed.

The ratio of the number-average molecular weight (Mn) of the first block copolymer and the number-average molecular weight (Mn) of the second block copolymer (number-average molecular weight (Mn) of second block copolymer/number-average molecular weight (Mn) of first block copolymer) is more than 1, and is preferably more than 1 and 1.1 or less, more preferably 1.02 or more and 1.1 or less, and still more preferably 1.04 or more and 1.08 or less.

In a case where the ratio of the number-average molecular weight (Mn) of first block copolymer and the number-average molecular weight (Mn) of the second block copolymer is within the above-described preferred range, the occurrence of defects can be further suppressed.

The resin composition for forming a phase-separated structure according to the present embodiment may contain three or more kinds of block copolymers. In a case where three or more kinds of block copolymers are contained, any one kind of block copolymers is the first block copolymer, and any one kind of block copolymer having a larger number-average molecular weight (Mn) than the first block copolymer is the second block copolymer.

A dispersity (Mw/Mn) of the second block copolymer is preferably 1.0 to 3.0, more preferably 1.0 to 1.5, and still more preferably 1.0 to 1.3.

### <Homopolymer A>

The homopolymer A is a homopolymer which is compatible with the first a block in the first block copolymer and the second a block in the second block copolymer described above.

In the present specification, the “homopolymer which is compatible with the first a block and the second a block” refers to a homopolymer having the same constitutional unit as the constitutional units constituting the first a block and the second a block, or a homopolymer having a constitutional unit in which a structure of the constitutional units constituting the first a block and the second a block is changed to such an extent that the compatibility does not change significantly.

As the homopolymer A having a constitutional unit in which a structure thereof is changed to such an extent that the compatibility does not change significantly, for example, in a case where the first a block and the second a block are blocks of the constitutional unit (u1) having an aromatic hydrocarbon group, a homopolymer having a constitutional unit in which the aromatic hydrocarbon group is substituted with an alkyl group having 1 to 5 carbon atoms is an exemplary example.

More specifically, as the homopolymer A, in a case where the first a block and the second a block are blocks of the constitutional units derived from styrene, polystyrene, α-methylstyrene, and the like are exemplary examples.

Among the above, the homopolymer A is preferably a homopolymer having the same constitutional unit as the constitutional units constituting the first a block and the second a block, and specifically, it is preferably polystyrene.

A number-average molecular weight (Mn) of the homopolymer A is preferably 1,000 or more and less than 30,000, more preferably 1,000 or more and 15,000 or less, still more preferably 1,500 or more and 8,000 or less, and particularly preferably 2,000 or more and 5,000 or less.

In a case where the number-average molecular weight (Mn) of the homopolymer A is equal to or more than the above-described preferred lower limit value, the process margin is further improved.

On the other hand, in a case where the number-average molecular weight (Mn) of the homopolymer A is equal to or less than the above-described preferred upper limit value, the occurrence of defects can be further suppressed.

One kind of the homopolymer A may be used alone, or two or more kinds thereof may be used in combination.

### <Homopolymer B>

The homopolymer B is a homopolymer which is compatible with the first b block in the first block copolymer and the second b block in the second block copolymer described above.

In the present specification, the “homopolymer which is compatible with the first b block and the second b block” refers to a homopolymer having the same constitutional unit as the constitutional units constituting the first b block and the second b block, or a homopolymer having a constitutional unit in which a structure of the constitutional units constituting the first b block and the second b block is changed to such an extent that the compatibility does not change significantly.

As the homopolymer B having a constitutional unit in which a structure thereof is changed to such an extent that the compatibility does not change significantly, for example, in a case where the first b block and the second b block are blocks of the constitutional unit (u2) derived from an (α-substituted)acrylic acid or (α-substituted)acrylic acid ester, a homopolymer having a constitutional unit derived from an (α-substituted)acrylic acid or (α-substituted)acrylic acid ester different from the (α-substituted)acrylic acid or (α-substituted)acrylic acid ester is an exemplary example.

More specifically, as the homopolymer B, in a case where the first b block and the second b block are blocks of the constitutional units derived from methyl methacrylate, poly(methyl methacrylate), poly(methyl acrylate), poly(ethyl acrylate), poly(t-butyl acrylate), poly(ethyl methacrylate), poly(t-butyl methacrylate), and the like are exemplary examples.

Among the above, the homopolymer B is preferably a homopolymer having the same constitutional unit as the constitutional units constituting the first b block and the second b block, and specifically, it is preferably poly(methyl methacrylate).

A number-average molecular weight (Mn) of the homopolymer B is preferably 1,000 or more and less than 30,000, more preferably 1,000 or more and 15,000 or less, still more preferably 1,500 or more and 8,000 or less, and particularly preferably 2,000 or more and 5,000 or less.

In a case where the number-average molecular weight (Mn) of the homopolymer B is equal to or more than the above-described preferred lower limit value, the process margin is further improved.

On the other hand, in a case where the number-average molecular weight (Mn) of the homopolymer B is equal to or less than the above-described preferred upper limit value, the occurrence of defects can be further suppressed.

One kind of the homopolymer B may be used alone, or two or more kinds thereof may be used in combination.

The total content of the homopolymers A and B is preferably 1 part by mass or more and less than 200 parts by mass, more preferably 5 parts by mass or more and 150 parts by mass or less, and still more preferably 10 parts by mass or more and 100 parts by mass or less with respect to 100 parts by mass of the total of the first block copolymer and the second block copolymer described above.

In a case where the total content of the homopolymers A and B with respect to the content of the first block copolymer and the second block copolymer is equal to or more than the above-described preferred lower limit value, the process margin is further improved.

On the other hand, in a case where the total content of the homopolymers A and B is equal to or less than the above-described preferred upper limit value, the occurrence of defects can be further suppressed.

The total content of the homopolymers A and B is preferably 60% by mass or less, more preferably 0.5% by mass or more and 60% by mass or less, still more preferably 1% by mass or more and 55% by mass or less, and particularly preferably 10% by mass or more and 50% by mass or less with respect to 100% by mass of the total solid content of the resin composition for forming a phase-separated structure according to the present embodiment.

In a case where the total content of the homopolymers A and B with respect to the total amount of the resin composition for forming a phase-separated structure is equal to or more than the above-described preferred lower limit value, the process margin is further improved.

On the other hand, in a case where the total content of the homopolymers A and B is equal to or less than the above-described preferred upper limit value, the occurrence of defects can be further suppressed.

It is preferable that a mass ratio of the content of the homopolymer A and the content of the homopolymer B is substantially the same as the mass ratio of the first a block and the first b block in the first block copolymer.

Here, the “substantially the same” means that, in a case where the mass ratio (1a:1b) of the first a block and the first b block in the first block copolymer is Xa:Yb (Xa+Yb=100), the content of the homopolymer A is Xa±10 parts by mass and the content of the homopolymer B is Yb±10 parts by mass (Xa+Yb=100).

Specifically, in a case where the mass ratio (1a:1b) of the first a block to the first b block in the first block copolymer is 60:40, it is preferable that, with respect to 100 parts by mass of the total of the first block copolymer and the second block copolymer, the content of the homopolymer A is in a range of 50 to 70 parts by mass and the content of the homopolymer B is in a range of 30 to 50 parts by mass (content of homopolymer A+content of homopolymer B=100 parts by mass).

As described above, since the mass ratio (1a:1b) of the first a block to the first b block in the first block copolymer is preferably 60:40 to 90:10 and more preferably 60:40 to 80:20, it is preferable that the mass ratio of the content of the homopolymer A and the content of the homopolymer B (content of homopolymer A:content of homopolymer B) is substantially the same or the same as the preferred mass ratio.

Among the above, it is preferable that a mass ratio of the content of the homopolymer A and the content of the homopolymer B is the same as the mass ratio of the first a block and the first b block in the first block copolymer described above.

In a case where the mass ratio (1a:1b) of the constitutional unit constituting the first a block and the constitutional unit constituting the first b block in the first block copolymer is different from the mass ratio (2a:2b) of the constitutional unit constituting the second a block and the constitutional unit constituting the second b block in the second block copolymer, it is preferable that the mass ratio of the content of the homopolymer A and the content of the homopolymer B is the same as a ratio of an average value of the first a block in the first block copolymer and the second a block in the second block copolymer and an average value of the first b block in the first block copolymer and the second b block in the second block copolymer, according to a content proportion of the first block copolymer and the second block copolymer.

Specifically, in a case where the content proportion of the first block copolymer and the second block copolymer is 50:50, the mass ratio of the constitutional unit constituting the first a block and the constitutional unit constituting the first b block in the first block copolymer is indicated by (1a:1b), and the mass ratio of the constitutional unit constituting the second a block and the constitutional unit constituting the second b block in the second block copolymer is indicated by (2a:2b), the mass ratio of the content of the homopolymer A and the content of the homopolymer B (content of homopolymer A:content of homopolymer B) is preferably (1a+2a)/2:(1b+2b)/2.

The mass ratio of the first a block and the first b block in the first block copolymer is a ratio obtained by multiplying the mass ratio of each block, which is calculated by NMR measurement, by a molecular weight of a monomer derived from the constitutional unit constituting the first a block or a molecular weight of a monomer derived from the constitutional unit constituting the first b block, in which the overall is determined to be 100%.

For example, in a case where the first block copolymer is a polystyrene-poly(methyl methacrylate) block copolymer, a mass ratio of a polystyrene block and a poly(methyl methacrylate) block can be calculated by multiplying a mass ratio of the polystyrene block or a mass ratio of the poly(methyl methacrylate) block, which is calculated by NMR measurement, by a molecular weight of styrene (104.15) or a molecular weight of methyl methacrylate (100.12), in which the overall is determined to be 100%.

### <Organic Solvent Component>

The resin composition for forming a phase-separated structure according to the present embodiment can be prepared by dissolving the first block copolymer, second block copolymer, homopolymer A, and homopolymer B described above in an organic solvent component.

Any organic solvent component may be used as long as it can dissolve each component to be used and form a homogeneous solution, and arbitrary solvents may be selected from any solvents known in the related art as a solvent for a composition containing a resin as a main component.

As the organic solvent component, for example, lactones such as γ-butyrolactone; ketones such as acetone, methyl ethyl ketone, cyclohexanone, methyl-n-pentyl ketone, methyl isopentyl ketone, and 2-heptanone; polyhydric alcohols such as ethylene glycol, diethylene glycol, propylene glycol, and dipropylene glycol; compounds having an ester bond such as ethylene glycol monoacetate, diethylene glycol monoacetate, propylene glycol monoacetate, or dipropylene glycol monoacetate; polyhydric alcohol derivatives such as compounds having an ether bond, for example, a monoalkylether such as monomethylether, monoethylether, monopropylether, or monobutylether or monophenylether of any of the polyhydric alcohols or the compounds having an ester bond [among these, propylene glycol monomethyl ether acetate (PGMEA), or propylene glycol monomethyl ether (PGME) is preferable]; cyclic ethers such as dioxane; esters such as methyl lactate, ethyl lactate (EL), methyl acetate, ethyl acetate, butyl acetate, methyl pyruvate, ethyl pyruvate, methyl methoxypropionate, and ethyl ethoxypropionate; aromatic organic solvents such as anisole, ethylbenzylether, cresylmethylether, diphenylether, dibenzylether, phenetole, butylphenylether, ethylbenzene, diethylbenzene, pentylbenzene, isopropylbenzene, toluene, xylene, cymene, and mesitylene; and the like are exemplary examples.

The organic solvent component may be used alone or as a mixed solvent of two or more kinds thereof. Among these, propylene glycol monomethyl ether acetate (PGMEA), propylene glycol monomethyl ether (PGME), cyclohexanone, or EL is preferable.

In addition, a mixed solvent obtained by mixing PGMEA with a polar solvent is also preferable. A blending ratio (mass ratio) of the mixed solvent can be appropriately determined in consideration of compatibility between PGMEA and the polar solvent, and it is preferably in a range of 1:9 to 9:1 and more preferably in a range of 2:8 to 8:2. For example, in a case where EL is blended as the polar solvent, a mass ratio of PGMEA:EL is preferably 1:9 to 9:1 and more preferably 2:8 to 8:2. In addition, in a case where PGME is blended as the polar solvent, a mass ratio of PGMEA:PGME is preferably 1:9 to 9:1, more preferably 2:8 to 8:2, and still more preferably 3:7 to 7:3. In addition, in a case where PGME and cyclohexanone are blended as the polar solvent, a mass ratio of PGMEA:(PGME+cyclohexanone) is preferably 1:9 to 9:1, more preferably 2:8 to 8:2, and still more preferably 3:7 to 7:3.

In addition, as the organic solvent component in the resin composition for forming a phase-separated structure, in addition to those solvents, a mixed solvent in which PGMEA, EL, or the above-described mixed solvent of PGMEA and a polar solvent is mixed with γ-butyrolactone is also preferable. In this case, as a mixing proportion, a mass ratio of the former and the latter is preferably set to 70:30 to 95:5.

The concentration of the organic solvent component contained in the resin composition for forming a phase-separated structure is not particularly limited, and the component is appropriately set at a concentration with which the coating can be performed according to the coating film thickness. A concentration of solid contents is generally used in a range of 0.2% to 70% by mass, preferably in a range of 0.2% to 50% by mass.

### <Optional Component>

The resin composition for forming a phase-separated structure according to the present embodiment may contain an optional component other than the first block copolymer, second block copolymer, homopolymer A, and homopolymer B described above.

As the optional component, other resins, a surfactant, a dissolution inhibitor, a plasticizer, a stabilizer, a colorant, a halation-preventing agent, a dye, a sensitizer, a base multiplier, a basic compound, and the like are exemplary examples.

As a preferred aspect of the resin composition for forming a phase-separated structure according to the present embodiment, the resin composition for forming a phase-separated structure contains a first polystyrene-poly(methyl methacrylate) block copolymer, a second polystyrene-poly(methyl methacrylate) block copolymer having a larger number-average molecular weight (Mn) than the first polystyrene-poly(methyl methacrylate) block copolymer, polystyrene, and poly(methyl methacrylate).

In addition, in the resin composition for forming a phase-separated structure, it is preferable that the number-average molecular weight (Mn), the content, and the mass ratio of the first polystyrene-poly(methyl methacrylate) block copolymer, the second polystyrene-poly(methyl methacrylate) block copolymer, the polystyrene, and the poly(methyl methacrylate) are within the above-described preferred range.

As a more preferred aspect of the resin composition for forming a phase-separated structure according to the present embodiment, the resin composition for forming a phase-separated structure contains a first polystyrene-poly(methyl methacrylate) block copolymer, a second polystyrene-poly(methyl methacrylate) block copolymer having a larger number-average molecular weight (Mn) than the first polystyrene-poly(methyl methacrylate) block copolymer, polystyrene, and poly(methyl methacrylate), in which a number-average molecular weight (Mn) of each of the first polystyrene-poly(methyl methacrylate) block copolymer and the second polystyrene-poly(methyl methacrylate) block copolymer is 98,000 to 120,000, a mass ratio of the first polystyrene-poly(methyl methacrylate) block copolymer and the second polystyrene-poly(methyl methacrylate) block copolymer (polystyrene:poly(methyl methacrylate)) is 70:30 to 72:28, a number-average molecular weights (Mn) of each of the polystyrene and the poly(methyl methacrylate) is 1,000 or 3,000, and the total content of the polystyrene and the poly(methyl methacrylate) is 15 to 55 parts by mass with respect to 100 parts by mass of the total content of the first polystyrene-poly(methyl methacrylate) block copolymer and the second polystyrene-poly(methyl methacrylate) block copolymer.

In the above-described resin composition for forming a phase-separated structure, the process margin in a case of forming the structure body can be further improved and the occurrence of defects can be further suppressed.

The resin composition for forming a phase-separated structure according to the present embodiment, which has been described above, contains, in addition to the first block copolymer, the second block copolymer having a larger number-average molecular weight (Mn) than the first block copolymer, the homopolymer A, and the homopolymer B.

Since the resin composition for forming a phase-separated structure according to the present embodiment contains the second block copolymer, a period of a structure body produced from the resin composition for forming a phase-separated structure can be in a certain width. Therefore, influence of a dimensional variation or the like of the guide pattern is alleviated, and the process margin is improved.

In addition, in the resin composition for forming a phase-separated structure in the related art, which contains one block copolymer and a plurality of specific homopolymers, by containing the homopolymers, the process margin can be improved by increasing a degree of freedom in the unique structure period, but there is a problem that defects are likely to occur by increasing the degree of freedom in the unique structure period.

On the other hand, in the resin composition for forming a phase-separated structure according to the present embodiment, since the second block copolymer is further contained in the configuration of the resin composition for forming a phase-separated structure in the related art, the problem that the defects occur by containing the plurality of homopolymers can be solved.

Therefore, with the resin composition for forming a phase-separated structure according to the present embodiment, in the production of the structure body including a phase-separated structure, the process margin can be improved and the occurrence of defects can be suppressed.

### (Method for Producing Structure Body Including Phase-Separated Structure)

The method for producing a structure body including a phase-separated structure according to the present embodiment includes a step of applying the resin composition for forming a phase-separated structure according to the above-described embodiment onto a support to form a layer containing the resin composition for forming a phase-separated structure, and a step of phase-separating the layer containing the resin composition for forming a phase-separated structure.

A preferred method for producing a structure body including a phase-separated structure according to the present embodiment includes a step of applying an undercoat agent onto a substrate to form an undercoat agent layer (hereinafter, also referred to as “step (i)”), a step of forming a layer containing the resin composition for forming a phase-separated structure of the above-described embodiment on the undercoat agent layer (hereinafter, also referred to as “step (ii)”), and a step of phase-separating the layer containing the resin composition for forming a phase-separated structure (hereinafter, also referred to as “step (iii)”).

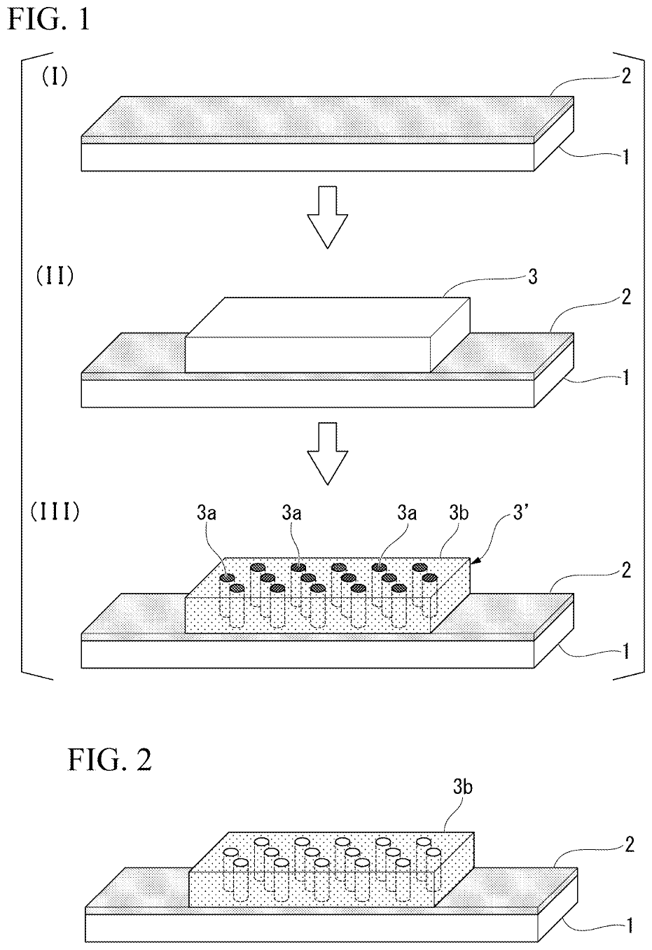

Hereinafter, the method for producing a structure body including a phase-separated structure will be specifically described with reference to FIG. 1. However, the present invention is not limited thereto.

FIG. 1 shows an exemplary embodiment of the method for producing a structure body including a phase-separated structure.

In the embodiment shown in FIG. 1, first, an undercoat agent layer 2 is formed by applying an undercoat agent onto a support 1 (FIG. 1(I); step (i)).

Next, the resin composition for forming a phase-separated structure of the above-described embodiment is applied onto the undercoat agent layer 2 to form a layer formed of the resin composition for forming a phase-separated structure of the above-described embodiment (hereinafter, also referred to as “BCP layer 3”) (FIG. 1(II); step (ii)).

Next, the BCP layer 3 is phase-separated into a phase 3a and a phase 3b by a heating and annealing treatment (FIG. 1(III); step (iii)).

According to the production method of the embodiment, that is, the production method including the steps (i) to (iii), a structure body 3′ including a phase-separated structure is produced on the support 1 on which the undercoat agent layer 2 has been formed.

[Step (i)]

In the step (i), the undercoat agent layer 2 is formed by applying an undercoat agent onto the support 1.

By providing the undercoat agent layer 2 on the support 1, it is possible to control hydrophilic and hydrophobic balance between a surface of the support 1 and the BCP layer 3.

In a case where the undercoat agent layer 2 contains a resin component having the constitutional units constituting the first a block and the second a block described above, adhesiveness between the support 1, and a phase including the first a block of the first block copolymer and a phase including the second a block of the second block copolymer in the BCP layer 3 is enhanced.

In a case where the undercoat agent layer 2 contains a resin component having the constitutional units constituting the first b block and the second b block described above, adhesiveness between the support 1, and a phase including the first b block of the first block copolymer and a phase including the second b block of the second block copolymer in the BCP layer 3 is enhanced.

Accordingly, a cylinder structure oriented in a direction perpendicular to the surface of the support 1 is likely to be formed due to the phase separation of the BCP layer 3.

### Undercoat Agent:

A resin composition can be used as the undercoat agent.

The resin composition for the undercoat agent can be appropriately selected from the resin compositions known in the related art, which are used for forming a thin film depending on the type of the first a block, second a block, first b block, and second b block described above.

The resin composition for the undercoat agent may be, for example, a thermopolymerizable resin composition or may be a photosensitive resin composition such as a positive-type resist composition or a negative-type resist composition. In addition, a non-polymerizable film formed by applying a compound as a surface treating agent may be used as the undercoat agent layer. For example, a siloxane-based organic monomolecular film formed by applying phenethyltrichlorosilane, octadecyltrichlorosilane, hexamethyldisilazane, or the like as a surface treating agent can also be suitably used as an undercoat agent layer.

Such a resin composition is preferably a resin composition containing a resin which has the same constitutional unit as the constitutional units of the first block copolymer and the second block copolymer.

For example, in a case where the first block copolymer and the second block copolymer are polystyrene-poly(methyl methacrylate) block copolymers, the resin composition is preferably a resin composition containing a resin which is obtained by polymerizing a monomer having an aromatic ring with a monomer having a highly polar functional group.

As the monomer having an aromatic ring, a monomer having an aryl group obtained by removing a hydrogen atom from an aromatic hydrocarbon ring, such as a phenyl group, a biphenyl group, a fluorenyl group, a naphthyl group, an anthryl group, and a phenanthryl group, or having a heteroaryl group in which carbon atoms constituting the ring of these groups are partially substituted with a heteroatom such as an oxygen atom, a sulfur atom, and a nitrogen atom is an exemplary example.

As the monomer having a highly polar functional group, a monomer having a trimethoxysilyl group, a trichlorosilyl group, an epoxy group, a glycidyl group, a carboxy group, a hydroxy group, a cyano group, a hydroxyalkyl group in which the hydrogen atoms of the alkyl group are partially substituted with a hydroxyl group, and the like is an exemplary example.

In a case where the first block copolymer and the second block copolymer are polystyrene-poly(methyl methacrylate) block copolymers, as the resin contained in the resin composition for the undercoat agent, specifically, a resin having a constitutional unit derived from styrene and a constitutional unit derived from an (α-substituted)acrylic acid ester (preferably, methyl methacrylate) is preferable; and a random copolymer having a constitutional unit derived from styrene and a constitutional unit derived from an (ax-substituted)acrylic acid ester (preferably, methyl methacrylate) or an alternating copolymer having a constitutional unit derived from styrene and a constitutional unit derived from an (α-substituted)acrylic acid ester (preferably, methyl methacrylate) is more preferable.

In addition, among these, a copolymer having a constitutional unit derived from styrene, a constitutional unit derived from methyl methacrylate, and a constitutional unit derived from 2-hydroxyethyl methacrylate is preferable.

The resin composition for the undercoat agent can be produced by dissolving the above-described resin in a solvent.

As such a solvent, any solvent may be used as long as it can dissolve each component to be used and form a homogeneous solution. For example, the same solvent as the organic solvent component exemplary described in the resin composition for forming a phase-separated structure according to the above-described embodiment is an exemplary example.

The type of the support 1 is not particularly limited as long as the resin composition can be applied onto its surface. For example, a substrate made of an inorganic material such as a metal (silicon, copper, chromium, iron, and aluminum), glass, titanium oxide, silica or mica; a substrate made of an oxide such as SiO₂; a substrate made of a nitride such as SiN; a substrate made of an oxynitride such as SiON; and a substrate made of an organic material such as acryl, polystyrene, cellulose, cellulose acetate, phenolic resin, and the like are exemplary examples. Among these, a metal substrate is suitable, and for example, a structure body having a cylinder structure is likely to be formed in a silicon substrate (Si substrate) or a copper substrate (Cu substrate). Among these, an Si substrate is particularly suitable.

The size and shape of the support 1 are not particularly limited. The support 1 is not necessarily required to have a smooth surface, and substrates of various shapes can be appropriately selected. For example, a substrate having a curved surface, a flat plate having a surface with an uneven shape, and a substrate with a flaky shape or the like are exemplary examples.

An inorganic and/or organic film may be provided on the surface of the support 1.

As the inorganic film, an inorganic antireflection film (inorganic BARC) is an exemplary example. As the organic film, an organic antireflection film (organic BARC) is an exemplary example.

The inorganic film can be formed, for example, by applying an inorganic antireflection film composition such as a silicon-based material onto a support and by sintering the film.

For example, the organic film can be formed by applying a material for forming an organic film, in which a resin component and the like constituting the film are dissolved in an organic solvent, onto a substrate using a spinner or the like, and baking the film under heating conditions at preferably 200° C. to 300° C. for preferably 30 to 300 seconds and more preferably 60 to 180 seconds. The material for forming an organic film does not necessarily need to have sensitivity to light or electron beams, which is essential for a resist film, and may have sensitivity or does not have to have sensitivity. Specifically, a resist or a resin generally used for the production of semiconductor elements or liquid crystal display elements can be used.

In addition, it is preferable that the material for forming an organic film is a material capable of forming an organic film which can be subjected to etching, particularly dry etching, so that the organic film can be etched by using a pattern formed from a block copolymer, which is formed by processing the BCP layer 3, to transfer the pattern onto the organic film, and an organic film pattern can be formed. Above all, the material for forming an organic film is preferably a material capable of forming an organic film capable of being subjected to etching such as oxygen plasma etching. Such a material for forming an organic film may be a material conventionally used for forming an organic film such as organic BARC. For example, ARC series manufactured by Nissan Chemical Industries, Ltd., AR series manufactured by Rohm and Haas Company, SWK series manufactured by Tokyo Ohka Kogyo Co., Ltd., and the like are exemplary examples.

A method of forming the undercoat agent layer 2 by applying the undercoat agent onto the support 1 is not particularly limited, and the undercoat agent layer 2 can be formed by a known method in the related art.

For example, the undercoat agent layer 2 can be formed by applying the undercoat agent onto the support 1 by a known method in the related art, such as using a spin coating or a spinner, to form a coating film, and drying the coating film.

As a method of drying the coating film, any method of drying the coating film may be used as long as the solvent contained in the undercoat agent can be volatilized, and for example, a method of baking the coating film is an exemplary example. In this case, a baking temperature is preferably 80° C. to 300° C., more preferably 180° C. to 270° C., and still more preferably 230° C. to 260° C. A baking time is preferably 30 to 500 seconds and more preferably 60 to 400 seconds.

The thickness of the undercoat agent layer 2 after drying the coating film is preferably approximately 10 to 100 nm and more preferably approximately 40 to 80 nm.

The surface of the support 1 may be cleaned in advance before forming the undercoat agent layer 2 on the support 1. Coatability of the undercoat agent is improved by cleaning the surface of the support 1.

Regarding the cleaning treatment method, known methods in the related art can be utilized, and an oxygen plasma treatment, an ozone oxidation treatment, an acid alkali treatment, a chemical modification treatment, and the like are exemplary examples.

After the undercoat agent layer 2 is formed, the undercoat agent layer 2 may be rinsed as necessary using a rinse liquid such as a solvent. Since uncrosslinked portions and the like in the undercoat agent layer 2 are removed by this rinsing, the affinity with at least one block constituting the block copolymer is improved, and a phase-separated structure including a cylinder structure oriented in a direction perpendicular to the surface of the support 1 is likely to be formed.

The rinse liquid may be any one which can dissolve the uncrosslinked portions, and a solvent such as propylene glycol monomethyl ether acetate (PGMEA), propylene glycol monomethyl ether (PGME), or ethyl lactate (EL), or a commercially available thinner liquid can be used.

In addition, after the cleaning, post-baking may be performed in order to volatilize the rinse liquid. A temperature condition of the post-baking is preferably 80° C. to 300° C., more preferably 100° C. to 270° C., and still more preferably 120° C. to 250° C. A baking time is preferably 30 to 500 seconds and more preferably 60 to 240 seconds. A thickness of the undercoat agent layer 2 after the post-baking is preferably approximately 1 to 10 nm and more preferably approximately 2 to 7 nm.

[Step (ii)]

In the step (ii), the BCP layer 3 is formed by applying the resin composition for forming a phase-separated structure onto the support 1 on which the undercoat agent layer 2 has been formed.

The method of forming the BCP layer 3 on the undercoat agent layer 2 is not particularly limited, and a method of applying the resin composition for forming a phase-separated structure according to the above-described embodiment onto the undercoat agent layer 2 by a known method in the related art, such as spin coating or using a spinner, to form a coating film, and drying the coating film is an exemplary example.

A drying temperature is preferably 60° C. to 120° C., and a drying time is preferably 30 to 100 seconds.

The thickness of the BCP layer 3 may be a thickness sufficient to induce phase separation, and when considering the type of the support 1, or the structure period size, the uniformity of the nano-structure bodies, or the like of the phase-separated structure to be formed, the thickness thereof is preferably 20 to 100 nm and more preferably 30 to 80 nm.

For example, in a case where the support 1 is an Si substrate, the thickness of the BCP layer 3 is preferably adjusted to 10 to 100 nm and more preferably 30 to 80 nm.

[Step (iii)]

In the step (iii), the BCP layer 3 formed on the support 1 is phase-separated.

By performing a heating and annealing treatment on the support 1 after the step (ii), the structure body 3′ including a phase-separated structure which is phase-separated into the phase 3a and the phase 3b is produced on the support 1.

The annealing treatment is preferably performed under a temperature condition of equal to or higher than a glass transition temperature of the first block copolymer and the second block copolymer used and lower than a thermal decomposition temperature. For example, in a case where the first block copolymer and the second block copolymer are polystyrene-poly(methyl methacrylate) (PS-b-PMMA) block copolymers (number-average molecular weight (Mn): 45,000 to 150,000), the temperature is preferably 180° C. to 270° C. The heating time is preferably 30 seconds to 30 minutes.

In addition, it is preferable that the annealing treatment is performed in a gas having low reactivity, such as nitrogen.

In the method for producing a structure body including a phase-separated structure according to the embodiment described above, since the resin composition for forming a phase-separated structure according to the embodiment described above is used, the process margin is large and the occurrence of defects is suppressed.

In addition, with the method for producing a structure body including a phase-separated structure according to the embodiment, it is possible to produce a support including, on the surface of the support, nano-structure bodies in which positions and orientations are more freely designed. For example, the formed structure body has high adhesiveness to the support and tends to have a phase-separated structure having a cylinder structure oriented in the direction perpendicular to the surface of the support.

### [Optional Step]

The method for producing a structure body including a phase-separated structure is not limited to the above-described embodiment, and may have a step (optional step) in addition to the steps (i) to (iii).

As such an optional step, a step of selectively removing, in the BCP layer 3, the phase including the first a block and the second a block or the phase including the first b block and the second b block among blocks constituting the first block copolymer and the second block copolymer described above (hereinafter, referred to as “step (iv)”), a guide pattern forming step, and the like are exemplary examples.

### Regarding Step (iv)

In the step (iv), selectively removing, in the BCP layer 3 formed on the undercoat agent layer 2, among blocks constituting the first block copolymer and the second block copolymer described above, the phase including the first a block and the second a block or the phase including the first b block and the second b block is selectively removed. As a result, a fine pattern (polymer nano-structure body) is formed.

For example, in a case where the phase-separated structure having a cylinder structure oriented in the direction perpendicular to the surface of the support is formed in the above-described step (iii), a hole pattern is formed by the step (iv).

As a method of selectively removing the phase including blocks, a method of performing an oxygen plasma treatment on the BCP layer 3, a method of performing a hydrogen plasma treatment on the BCP layer 3, a method of irradiating the BCP layer 3 with ultraviolet rays and performing solvent development, and the like are exemplary examples.

For example, after the BCP layer 3 is phase-separated, the BCP layer 3 is subjected to an oxygen plasma treatment, a hydrogen plasma treatment, or the like, so that the phase including the first a block and the second a block is not selectively removed, and the phase including the first b block and the second b block is selectively removed.

In addition, for example, after the BCP layer 3 is phase-separated, the BCP layer 3 is irradiated with ultraviolet rays and subjected to development with a solvent (for example isopropyl alcohol), so that the phase including the first a block and the second a block is not selectively removed, and the phase including the first b block and the second b block is selectively removed.

FIG. 2 shows an exemplary embodiment of the step (iv).

In the embodiment shown in FIG. 2, in a case where the phase 3a is selectively removed and a pattern (polymer nano-structure body) from the separated phase 3b is formed by performing an oxygen plasma treatment on the structure body 3′ produced on the support 1 in the step (iii). In this case, the phase 3b is a phase including the first a block and the second a block, and the phase 3a is a phase including the first b block and the second b block.

The support 1 having the patterns formed by the phase separation of the BCP layer 3 as described above can be used as it is, but the shape of the pattern (polymer nano-structure body) of the support 1 may be changed by further heating.

Regarding temperature conditions for heating, a temperature equal to or higher than the glass transition temperature of the first block copolymer and the second block copolymer used and lower than the thermal decomposition temperature is preferable. In addition, the heating is preferably performed in a gas having low reactivity, such as nitrogen.

### Regarding Guide Pattern Forming Step

In the method for producing a structure body including a phase-separated structure, a step (guide pattern forming step) of forming a guide pattern on the undercoat agent layer may be provided between the step (i) and the step (ii) described above. As a result, it is possible to control an array structure of the phase-separated structure.

For example, in a case where the guide pattern is not provided, even for a block copolymer with which a random fingerprint-shaped phase-separated structure is formed, in a case where a groove structure of a resist film is provided on the surface of the undercoat agent layer, a phase-separated structure oriented along the grooves is obtained. According to such a principle, the guide pattern may be provided on the undercoat agent layer 2. In addition, in a case where a surface of the guide pattern has an affinity with any of the blocks constituting the first block copolymer and the second block copolymer described above, a phase-separated structure having a cylinder structure oriented in the direction perpendicular to the surface of the support is likely to be formed.

The guide pattern can be formed, for example, using a resist composition.

As the resist composition for forming the guide pattern, among resist compositions and modified products thereof, which are generally used for formation of a resist pattern, any one having the affinity with any of the blocks constituting the first block copolymer and the second block copolymer described above can be appropriately selected and used. The resist composition may be any of a positive-type resist composition for forming a positive-type pattern in which the exposed part of the resist film is dissolved and removed, or a negative-type resist composition for forming a negative-type pattern in which the unexposed part of the resist film is dissolved and removed; but the resist composition is preferably a negative-type resist composition. As the negative-type resist composition, for example, a resist composition containing an acid generator, and a base material component in which solubility in a liquid developer containing an organic solvent is decreased by the action of an acid, and in which the base material component contains a resin component having a constitutional unit which is decomposed by the action of an acid to have increased polarity, is preferable.

After the BCP composition is poured on the undercoat agent layer on which the guide pattern has been formed, an annealing treatment is performed to induce phase separation. Therefore, the resist composition for forming the guide pattern is preferably a composition capable of forming a resist film having excellent solvent resistance and heat resistance.

In the method for producing a structure body including a phase-separated structure according to the present embodiment, since the resin composition for forming a phase-separated structure according to the embodiment described above is used, even in the production method including the above-described guide pattern forming step, it is possible to suppress the occurrence of defects while improving the process margin.

### EXAMPLES

Hereinafter, the present invention will be described in more detail with reference to examples, but the present invention is not limited to these examples.

### <Preparation of Resin Composition for Forming Phase-Separated Structure>

Each component shown in Table 1 was dissolved in propylene glycol monomethyl ether acetate (PGMEA) and mixed to prepare a resin composition for forming a phase-separated structure (concentration of solid contents: 1.5% by mass) in each of Examples.

In addition, Table 1 also shows the total content (part by mass) of the homopolymer A and the homopolymer B in the resin composition for forming a phase-separated structure in each of Examples as “Total content of homopolymer A and homopolymer B”, and the ratio of the number-average molecular weight of the first block copolymer and the number-average molecular weight of the second block copolymer (number-average molecular weight of second block copolymer/number-average molecular weight of first block copolymer) as “Ratio of number-average molecular weights”.

TABLE 1

| | | | | | Total | |
|---|---|---|---|---|---|---|
| | | | | | content of | Ratio of |
| | | | | | homopolymer | number- |
| | | | | | A and | average |
| | First block | Second block | Homopolymer | Homopolymer | homopolymer | molecular |
| | copolymer | copolymer | A | B | B | weights |
| Example 1 | BCP1-1 | BCP1-2 | PS1 | PMMA1 | 20 | 1.06 |
| | (100 k) | (106 k) | (2 k) | (2 k) | | |
| | [50] | [50] | [14.2] | [5.8] | | |
| Example 2 | BCP2-1 | BCP2-2 | PS1 | PMMA1 | 30 | 1.08 |
| | (102 k) | (110 k) | (2 k) | (2 k) | | |
| | [50] | [50] | [21.3] | [8.7] | | |
| Example 3 | BCP3-1 | BCP3-2 | PS1 | PMMA1 | 50 | 1.05 |
| | (110 k) | (116 k) | (2 k) | (2 k) | | |
| | [50] | [50] | [35.5] | [14.5] | | |
| Example 4 | BCP4-1 | BCP4-2 | PS2 | PMMA2 | 20 | 1.05 |
| | (95 k) | (100 k) | (5 k) | (5 k) | | |
| | [50] | [50] | [14.2] | [5.8] | | |
| Example 5 | BCP5-1 | BCP5-2 | PS1 | PMMA1 | 20 | 1.06 |
| | (96 k) | (102 k) | (2 k) | (2 k) | | |
| | [50] | [50] | [13.2] | [6.8] | | |
| Example 6 | BCP6-1 | BCP6-2 | PS1 | PMMA1 | 20 | 1.06 |
| | (104 k) | (110 k) | (2 k) | (2 k) | | |
| | 50] | [50] | [14.6] | [5.4] | | |
| Example 7 | BCP7-1 | BCP7-2 | PS1 | PMMA2 | 20 | 1.06 |
| | (100 k) | (106 k) | (2 k) | (5 k) | | |
| | [50] | [50] | [14.2] | [5.8] | | |
| Example 8 | BCP8-1 | BCP8-2 | PS1 | PMMA1 | 20 | 1.04 |
| | (96 k) | (100 k) | (2 k) | (2 k) | | |
| | [50 | [50] | [13.7] | [6.3] | | |
| Example 9 | BCP9-1 | BCP9-2 | PS1 | PMMA1 | 10 | 1.07 |
| | (45 k) | (48 k) | (2 k) | (2 k) | | |
| | [50] | [50] | [7.1] | [2.9] | | |
| Example 10 | BCP10-1 | BCP10-2 | PS1 | PMMA1 | 100 | 1.04 |
| | (144 k) | (150 k) | (2 k) | (2 k) | | |
| | [50] | [50] | [73] | [27] | | |
| Example 11 | BCP1-1 | BCP1-2 | PS1 | PMMA1 | 20 | 1.06 |
| | (100 k) | (106 k) | (2 k) | (2 k) | | |
| | [50] | [50] | [17.8] | [2.2] | | |
| Example 12 | BCP1-1 | BCP1-2 | PS1 | PMMA1 | 20 | 1.06 |
| | (100 k) | (106 k) | (2 k) | (2 k) | | |
| | [50] | [50] | [10.6] | [9.4] | | |
| Comparative | BCP11-1 | — | — | — | — | — |
| Example 1 | (98 k) | | | | | |
| | [100] | | | | | |
| Comparative | BCP12-1 | — | PS1 | PMMA1 | 20 | — |
| Example 2 | (100 k) | | (2 k) | (2 k) | | |
| | [100] | | [13.2] | [6.8] | | |
| Comparative | BCP1-1 | BCP1-2 | PS1 | — | 20 | 1.06 |
| Example 3 | (100 k) | (106 k) | (2 k) | | | |
| | [50] | [50] | [20] | | | |
| Comparative | BCP1-1 | BCP1-2 | — | PMMA1 | 20 | 1.06 |
| Example 4 | (100 k) | (106 k) | | (2 k) | | |
| | [50] | [50] | | [20] | | |

In Table 1, each abbreviation has the following meaning. A numerical value in the brackets is a blending amount (part by mass).
BCP 1-1 (100 k): block copolymer of polystyrene and poly(methyl methacrylate) (PS-b-PMMA); number-average molecular weight (Mn): 100,000, PS/PMMA compositional ratio (mass ratio): 71/29
BCP 1-2 (106 k): PS-b-PMMA; number-average molecular weight (Mn): 106,000, PS/PMMA compositional ratio (mass ratio): 71/29
BCP 2-1 (102 k): PS-b-PMMA; number-average molecular weight (Mn): 102,000, PS/PMMA compositional ratio (mass ratio): 71/29
BCP 2-2 (110 k): PS-b-PMMA; number-average molecular weight (Mn): 110,000, PS/PMMA compositional ratio (mass ratio): 71/29
BCP 3-1 (110 k): PS-b-PMMA; number-average molecular weight (Mn): 110,000, PS/PMMA compositional ratio (mass ratio): 71/29
BCP 3-2 (116 k): PS-b-PMMA; number-average molecular weight (Mn): 116,000, PS/PMMA compositional ratio (mass ratio): 71/29
BCP 4-1 (95 k): PS-b-PMMA; number-average molecular weight (Mn): 95,000, PS/PMMA compositional ratio (mass ratio): 71/29
BCP 4-2 (100 k): PS-b-PMMA; number-average molecular weight (Mn): 100,000, PS/PMMA compositional ratio (mass ratio): 71/29
BCP 5-1 (96 k): PS-b-PMMA; number-average molecular weight (Mn): 96,000, PS/PMMA compositional ratio (mass ratio): 66/34
BCP 5-2 (102 k): PS-b-PMMA; number-average molecular weight (Mn): 102,000, PS/PMMA compositional ratio (mass ratio): 66/34
BCP 6-1 (104 k): PS-b-PMMA; number-average molecular weight (Mn): 104,000, PS/PMMA compositional ratio (mass ratio): 73/27
BCP 6-2 (110 k): PS-b-PMMA; number-average molecular weight (Mn): 110,000, PS/PMMA compositional ratio (mass ratio): 73/27
BCP 7-1 (100 k): PS-b-PMMA; number-average molecular weight (Mn): 100,000, PS/PMMA compositional ratio (mass ratio): 71/29
BCP 7-2 (106 k): PS-b-PMMA; number-average molecular weight (Mn): 106,000, PS/PMMA compositional ratio (mass ratio): 71/29
BCP 8-1 (96 k): PS-b-PMMA; number-average molecular weight (Mn): 96,000, PS/PMMA compositional ratio (mass ratio): 66/34
BCP 8-2 (100 k): PS-b-PMMA; number-average molecular weight (Mn): 100,000, PS/PMMA compositional ratio (mass ratio): 71/29
BCP 9-1 (45 k): PS-b-PMMA; number-average molecular weight (Mn): 45,000, PS/PMMA compositional ratio (mass ratio): 70/30
BCP 9-2 (48 k): PS-b-PMMA; number-average molecular weight (Mn): 48,000, PS/PMMA compositional ratio (mass ratio): 72/28
BCP 10-1 (144 k): PS-b-PMMA; number-average molecular weight (Mn): 144,000, PS/PMMA compositional ratio (mass ratio): 73/27
BCP 10-2 (150 k): PS-b-PMMA; number-average molecular weight (Mn): 150,000, PS/PMMA compositional ratio (mass ratio): 73/27
BCP 11-1 (98 k): PS-b-PMMA; number-average molecular weight (Mn): 98,000, PS/PMMA compositional ratio (mass ratio): 71/29
BCP 12-1 (100 k): PS-b-PMMA; number-average molecular weight (Mn): 100,000, PS/PMMA compositional ratio (mass ratio): 66/34

In the above description, even different abbreviations in the table, in a case where the number-average molecular weight (Mn) and the PS/PMMA compositional ratio (mass ratio) are the same, the block copolymers are the same block copolymer (PS-b-PMMA).
PS1 (2 k): polystyrene; number-average molecular weight (Mn): 2,000
PS2 (5 k): polystyrene; number-average molecular weight (Mn): 5,000
PMNMA1 (2 k): poly(methyl methacrylate); number-average molecular weight (Mn): 2,000
PMMA2 (5 k): poly(methyl methacrylate); number-average molecular weight (Mn): 5,000

### <Formation of Hole Pattern>

Using the resin composition for forming a phase-separated structure in each of Examples described above, a structure body including a phase-separated structure was formed by the following steps (i) to (iii), and a hole pattern was formed by the step (iv).

### Step (i):

A resin composition for an undercoat agent (a copolymer of polystyrene/poly(methyl methacrylate)/poly(2-hydroxyethyl methacrylate), compositional ratio (mass ratio): polystyrene/poly(methyl methacrylate)/poly(2-hydroxyethyl methacrylate)=82/12/6) prepared in a PGMEA solution having a concentration of 2 wt % was applied onto a 12-inch silicon wafer using a spinner, and sintered and dried at 250° C. for 300 seconds to form an undercoat agent layer having a film thickness of 60 nm on a substrate.

### Step (ii):

Next, a portion of the undercoat agent layer other than a substrate adhesion portion was removed with OK73 thinner (manufactured by Tokyo Ohka Kogyo Co., Ltd.), the undercoat agent layer was spin-coated with the resin composition for forming a phase-separated structure in each of Examples, and the resin composition for forming a phase-separated structure was soft-baked at 90° C. for 60 seconds for drying, thereby forming a layer of the resin composition for forming a phase-separated structure, having a film thickness of 45 nm.

Step (iii):

The substrate was heated at 260° C. for 15 minutes under a nitrogen stream and annealed to form a phase-separated structure (cylinder structure).

### Step (iv):

The substrate on which the phase-separated structure had been formed was irradiated with ultraviolet rays using CLEAN TRACK LITHUS Pro-Z (manufactured by Tokyo Electron Limited.), and developed with isopropyl alcohol to selectively remove a phase including PMMA, thereby forming a hole pattern.

### [Evaluation of Opening Ratio]

With regard to each of the hole patterns formed in <Formation of hole pattern> described above, image analysis was performed using image analysis software (DSA-APPS, manufactured by Hitachi High-Tech Corporation) to obtain an opening ratio (%) of each hole pattern. A proportion of good circular holes formed was regarded as the opening ratio. The results are shown in Table 2.

### [Evaluation of Number of Grain Holes]

With regard to each of the hole patterns formed in <Formation of hole pattern> described above, image analysis was performed using image analysis software (DSA-APPS, manufactured by Hitachi High-Tech Corporation) to obtain, from a 1350 nm-squire image, an average value of the number of good circular holes in the grains (number of grain holes). As the number of grain holes is larger, hole patterns having the same pitch and shape are formed more continuously, that is, an increase in process margin and a decrease in defects. The results are shown in Table 2.

TABLE 2

| | Opening ratio | Number of grain |
|---|---|---|
| | (%) | holes (piece) |
| Example 1 | 94.4 | 198 |
| Example 2 | 94.5 | 219 |
| Example 3 | 94.3 | 219 |
| Example 4 | 94.8 | 165 |
| Example 5 | 94.2 | 159 |
| Example 6 | 94.7 | 170 |
| Example 7 | 94.4 | 177 |
| Example 8 | 94.6 | 167 |
| Example 9 | 94.4 | 187 |
| Example 10 | 94.1 | 323 |
| Example 11 | 94.5 | 192 |
| Example 12 | 93.8 | 190 |
| Comparative | 89.5 | 106 |
| Example 1 | | |
| Comparative | 87.7 | 110 |
| Example 2 | | |
| Comparative | 94.1 | 101 |
| Example 3 | | |
| Comparative | 94.2 | 131 |
| Example 4 | | |

From the results shown in Table 2, it was confirmed that the hole pattern formed by using the resin composition for forming a phase-separated structure of Examples had a higher opening ratio and a higher number of grain holes as compared with the hole pattern formed by using the resin composition for forming a phase-separated structure of Comparative Examples.

Therefore, according to the resin composition for forming a phase-separated structure of Example, it was confirmed that the process margin was improved and the occurrence of defects could be suppressed.

Although preferred examples of the present invention are described above, the present invention is not limited to these examples. It is possible to add other configurations or to omit, replace, or modify the configurations described herein without departing from the spirit of the present invention. The present invention is not limited by the above description, but only by the scope of the appended claims.

### REFERENCE SIGNS LIST

1: Support
2: Undercoat agent layer
3: BCP layer
3′: Structure body
3a: Phase
3b: Phase

What is claimed is:

1. A resin composition for forming a phase-separated structure, comprising:
a first block copolymer having a first a block and a first b block;
a second block copolymer having a second a block and a second b block;
a homopolymer A compatible with the first a block and the second a block; and
a homopolymer B compatible with the first b block and the second b block,
wherein a constitutional unit constituting the first a block and a constitutional unit constituting the second a block are the same,
a constitutional unit constituting the first b block and a constitutional unit constituting the second b block are the same, and
a number-average molecular weight of the second block copolymer is larger than a number-average molecular weight of the first block copolymer.

2. The resin composition for forming a phase-separated structure according to claim 1,
wherein a ratio of the number-average molecular weight of the first block copolymer and the number-average molecular weight of the second block copolymer is more than 1 and 1.1 or less.

3. The resin composition for forming a phase-separated structure according to claim 1, wherein the homopolymer A is a homopolymer having the same constitutional unit as the constitutional units constituting the first a block and the second a block, and
the homopolymer B is a homopolymer having the same constitutional unit as the constitutional units constituting the first b block and the second b block.

4. The resin composition for forming a phase-separated structure according to claim 1, wherein a mass ratio of a content of the homopolymer A and a content of the homopolymer B is substantially the same as a mass ratio of the first a block and the first b block in the first block copolymer.

5. The resin composition for forming a phase-separated structure according to claim 1, wherein the first block copolymer and the second block copolymer are polystyrene-poly(methyl methacrylate) block copolymers, the homopolymer A is polystyrene, and the homopolymer B is poly(methyl methacrylate).

6. A method for producing a structure body including a phase-separated structure, the method comprising:
applying the resin composition for forming a phase-separated structure according to claim 1 onto a support to form a layer containing the resin composition for forming a phase-separated structure; and
phase-separating the layer containing the resin composition for forming a phase-separated structure.
